(19) United States
(12) Patent Application Publication
(10) Pub. No.: US 2019/0165305 A1
(43) Pub. Date: May 30, 2019

(54) OLED DISPLAY PANEL AND MANUFACTURING METHOD THEREOF

(71) Applicant: SHENZHEN CHINA STAR OPTOELECTRONICS SEMICONDUCTOR DISPLAY TECHNOLOGY CO., LTD., Shenzhen (CN)

(72) Inventor: Liangfen ZHANG, Shenzhen (CN)

(21) Appl. No.: 15/928,604

(22) Filed: Mar. 22, 2018

Related U.S. Application Data
(63) Continuation of application No. PCT/CN2018/072725, filed on Jan. 15, 2018.

(30) Foreign Application Priority Data
Nov. 28, 2017 (CN) 201711213632.6

(51) Int. Cl. H01L 51/52; H01L 27/32

(52) U.S. Cl. CPC H01L 51/5228; H01L 2227/323; H01L 27/3279

(57) ABSTRACT

The present disclosure discloses an OLED display panel, including: a first substrate, a planarization layer, an auxiliary electrode, an anode formed on the planarization layer, a pixel definition layer, a cathode isolation column, an organic light-emitting layer, a cathode formed on the organic light-emitting layer. The cathode including a light-emitting cathode and an isolation cathode, the light-emitting cathode being disposed on the pixel definition layer and the pixel region, the isolation cathode being disposed on the cathode isolation column, the light-emitting cathode and the isolation cathode being isolated from each other by the cathode isolation column. An electrode stage electrically connected directly or indirectly to the auxiliary electrode, the cathode isolation column being formed on the electrode stage, the electrode stage electrically connected to the light-emitting cathode for the light-emitting cathode to receive a voltage on the auxiliary electrode. A manufacturing method of an OLED display panel also disclosed.

### RELATED APPLICATIONS

This application is a continuation application of PCT Patent Application No. PCT/CN2018/072725, filed Jan. 15, 2018, which claims the priority benefit of Chinese Patent Application No. CN 201711213632.6, filed Nov. 28, 2017, which is herein incorporated by reference in its entirety.

### FIELD OF THE DISCLOSURE

The present disclosure relates to a display technology field, and more particularly to an OLED display panel and a manufacturing method thereof.

### BACKGROUND OF THE DISCLOSURE

Organic Light-Emitting Diode (OLED) display panels are favored by people for their thinness, energy saving, wide viewing angle, wide color gamut, and high contrast ratio. In recent years, their development is rapidly changing, and they are not only capable of producing curved displays but also gradually developing large sizes. However, the large size OLED display panel has a problem of IR Drop due to the large size, that is, there is a voltage drop in the long-distance transmission of voltage, resulting in a visually visible Mura (uneven display). To improve this problem, see FIG. 1, the OLED display panel is technically fabricated with the auxiliary electrode 121 and the cathode isolation column 150. The cathode 146 is isolated by the cathode isolation column 150 so as to separately control the cathode 146 and reduce IR Drop.

However, during the manufacturing of the OLED display panel, if the angle of the organic light-emitting layer 136 or the cathode isolation column 150 is not properly controlled, the cathode 150 can not be electrically connected to the auxiliary electrode 121. Please refer to the dotted area in FIG. 2, resulting in the OLED display panel is abnormal.

### SUMMARY OF THE DISCLOSURE

The technical problem to be solved in the embodiments of the present disclosure is to provide an OLED display panel and a manufacturing method thereof. The case where the cathode can not be electrically connected with the auxiliary electrode can be improved.

In order to solve the above technical problem, an embodiment of the first aspect of the present disclosure provides an OLED display panel; including: a first substrate;

a planarization layer formed on the first substrate;
an auxiliary electrode formed on the first substrate;
an anode formed on the planarization layer;
a pixel definition layer formed on the anode and the planarization layer; the pixel definition layer defining a plurality of pixel regions;
a cathode isolation column formed on the auxiliary electrode;
an organic light-emitting layer formed on the pixel definition layer, the anode, the auxiliary electrode, and the cathode isolation column;
a cathode formed on the organic light-emitting layer, the cathode including a light-emitting cathode and an isolation cathode, the light-emitting cathode being disposed on the pixel definition layer and the pixel region, the isolation cathode being disposed on the cathode isolation column, the light-emitting cathode and the isolation cathode being isolated from each other by the cathode isolation column; and
an electrode stage electrically connected directly or indirectly to the auxiliary electrode, the cathode isolation column being formed on the electrode stage, the electrode stage electrically connected to the light-emitting cathode for the light-emitting cathode to receive a voltage on the auxiliary electrode.

The upper surface of the electrode stage is higher than the upper surface of the edge portion of the light-emitting cathode electrically connected thereto, and the edge portion of the light-emitting cathode is electrically connected to the sidewall of the electrode stage.

The auxiliary electrode includes a transfer electrode and a connection electrode, the transfer electrode is located below the planarization layer, and the connection electrode electrically connects the transfer electrode and the electrode stage respectively.

The connection electrode includes a first connection electrode and a second connection electrode, the OLED display panel further includes a buffer layer and an interlayer insulating layer, the buffer layer is located on the first substrate, the interlayer insulating layer is located on the buffer layer, the planarization layer is located on the interlayer insulating layer, wherein the transfer electrode is located between the first substrate and the buffer layer, the first connection electrode is located on the interlayer insulating layer, and electrically connected to the transfer electrode by a dug hole on the interlayer insulating layer, the second connection electrode is located on the planarization layer and electrically connected to the first connection electrode by a dug hole on the planarization layer, the electrode stage is located above the second connection electrode.

One of or both the organic light-emitting layer and the cathode is formed by vapor deposition or printing.

A second aspect of the present disclosure provides a manufacturing method of an OLED display panel, including:

providing a first substrate;
forming a planarization layer on the first substrate;
forming an auxiliary electrode on the first substrate;
forming an anode on the planarization layer;
forming a pixel definition layer on the anode and the planarization layer, the pixel definition layer defining a plurality of pixel regions;
forming a cathode isolation column on the auxiliary electrode;

forming an organic light-emitting layer on the pixel definition layer, the anode, the auxiliary electrode, and the cathode isolation column;

forming a cathode on the organic light-emitting layer, the cathode including a light-emitting cathode and an isolation cathode, the light-emitting cathode being disposed on the pixel definition layer and the pixel region, the isolation cathode being disposed on the cathode isolation column, the light-emitting cathode and the isolation cathode being isolated from each other by the cathode isolation column; wherein the manufacturing method of an OLED display panel further includes: forming an electrode stage, the electrode stage being electrically connected directly or indirectly to the auxiliary electrode, the cathode isolation column being formed on the electrode stage, the electrode stage electrically connected to the light-emitting cathode for the light-emitting cathode to receive a voltage on the auxiliary electrode.

The upper surface of the electrode stage is higher than the upper surface of the edge portion of the light-emitting cathode electrically connected thereto, and the edge portion of the light-emitting cathode is electrically connected to the sidewall of the electrode stage.

The auxiliary electrode includes a transfer electrode and a connection electrode, the transfer electrode is located below the planarization layer, and the connection electrode electrically connects the transfer electrode and the electrode stage respectively.

The connection electrode includes a first connection electrode and a second connection electrode, the OLED display panel further includes a buffer layer and an interlayer insulating layer, the buffer layer is located on the first substrate, the interlayer insulating layer is located on the buffer layer, the planarization layer is located on the interlayer insulating layer, wherein the transfer electrode is located between the first substrate and the buffer layer, the first connection electrode is located on the interlayer insulating layer, and electrically connected to the transfer electrode by a dug hole on the interlayer insulating layer, the second connection electrode is located on the planarization layer and electrically connected to the first connection electrode by a dug hole on the planarization layer, the electrode stage is located above the second connection electrode.

One of or both the organic light-emitting layer and the cathode is formed by vapor deposition or printing.

The implementation of the embodiments of the present disclosure has the following beneficial effects:

Since the OLED display panel includes an electrode stage, the electrode stage is electrically connected with the auxiliary electrode directly or indirectly, the cathode isolation column is formed on the electrode stage and the electrode stage is electrically connected to the light-emitting cathode for the light-emitting cathode to receive a voltage on the auxiliary electrode. Therefore, even if the light-emitting cathode is not directly electrically connected to the second connection electrode, the light-emitting cathode can be electrically connected to the auxiliary electrode through the electrode stage, so that the voltage signal on the auxiliary electrode is stably transmitted to the cathode.

### BRIEF DESCRIPTION OF THE DRAWINGS

To describe the technical solutions in the embodiments of the present disclosure or in the prior art more clearly, the following briefly introduces the accompanying drawings required for describing the embodiments or the prior art. Apparently, the accompanying drawings in the following description show merely some embodiments of the present disclosure, and a person of ordinary skill in the art may still derive other drawings from these accompanying drawings without creative efforts.

FIG. 1 is a cross-sectional view of the cathode and the auxiliary electrode overlapped in the prior art OLED display panel.

FIG. 2 is a cross-sectional view of the cathode and the auxiliary electrode non-overlapped in the prior art OLED display panel.

FIG. 3 is a cross-sectional view of the OLED display panel according to the embodiment of the present disclosure.

FIG. 4 is a flowchart of the manufacturing method of an OLED display panel according to the embodiment of the present disclosure.

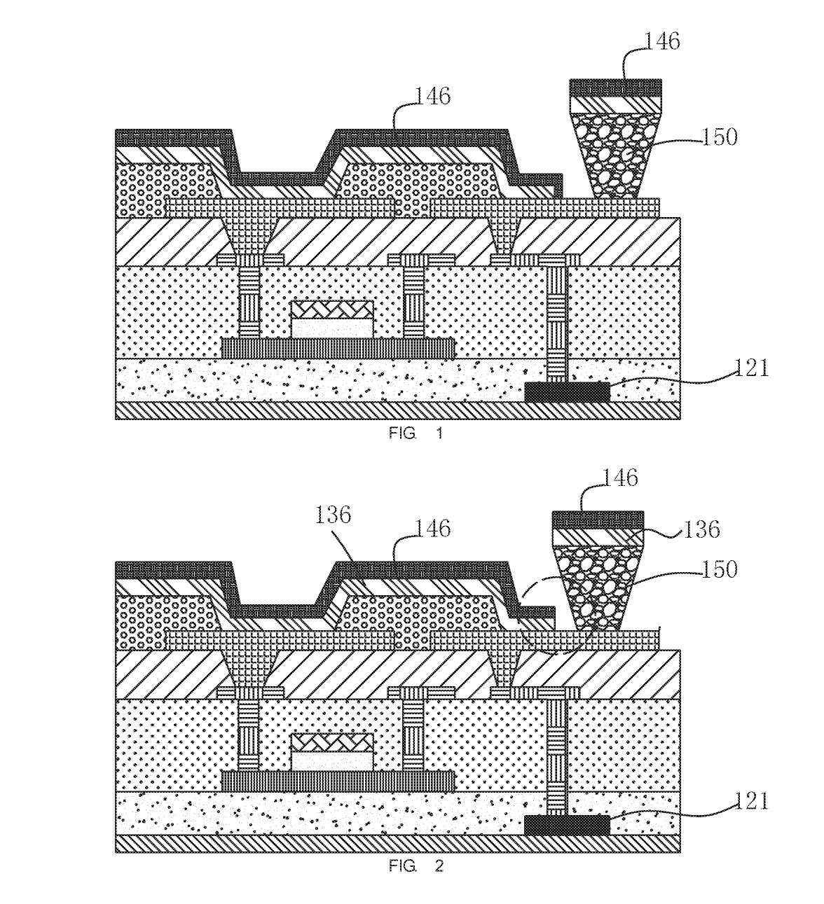

### DETAILED DESCRIPTION OF PREFERRED EMBODIMENTS

The technical solutions in the embodiments of the present disclosure will be described clearly and completely hereinafter with reference to the accompanying drawings in the embodiments of the present disclosure. Apparently, the described embodiments are merely some but not all embodiments of the present disclosure. All other embodiments obtained by persons of ordinary skill in the art based on the embodiments of the present disclosure without creative efforts shall fall within the protection scope of the present disclosure.

The terms “including” and “having,” as well as any variations thereof, appearing in the specification, claims and drawings, are intended to cover the inclusion of non-exclusive. For example, a process, method, system, product, or device that incorporates a series of steps or units is not limited to the steps or units listed, but may optionally include steps or units not listed, or optionally further steps or units inherent to these processes, methods, products or devices. In addition, the terms “first”, “second” and “third” are used to distinguish different objects and are not intended to describe a specific order.

An embodiment of the present disclosure provides an OLED display panel. Referring to FIG. 3, the OLED display panel includes a first substrate 210, a planarization layer 234, an auxiliary electrode, an anode 245, a pixel definition layer 235, a cathode isolation column 250, an organic light-emitting layer 236 and a cathode 246.

In this embodiment, the first substrate 210 is an array substrate, and the first substrate 210 is a glass substrate. In this embodiment, the OLED display panel is an AMOLED (Active-matrix organic light-emitting diode) display panel. Therefore, a thin film transistor is disposed on the first substrate 210, and the thin film transistor may be an amorphous silicon thin film transistor or a polycrystalline silicon thin film transistor, for example, a low temperature polysilicon thin film transistor. The method for preparing the polycrystalline silicon material can be, for example, Rapid Thermal Annealing (RTA), Excimer Laser Crystallization (ELC), Solid Phase Crystallization (SPC), Sequential Lateral Solidification (SLS) and Metal-Induced Crystallization (MIC) technology. In this embodiment, a buffer layer 231 is disposed on the first substrate 210, a semiconductor layer 241 is disposed on the buffer layer 231, the semiconductor layer 241 is an IGZO material, a gate insulating layer 232 is disposed on the semiconductor layer 241. A gate 242, and a scan line are disposed on the gate insulating layer 232. An interlayer insulating layer 233 (ILD) is disposed above the gate 242, the scan line, the semiconductor layer 241 and the buffer layer 231. The interlayer insulating layer 233 is provided with a source 244, a drain 243, and a data line. The source electrode 244 is electrically connected to the corresponding data line, and the source electrode 244 and the drain electrode 243 are electrically connected to the two ends of the semiconductor layer 241 by digging holes. In this embodiment, the gate 242, the source 244 and the drain 243 form three terminals of the thin film transistor. In addition, in other embodiments of the present disclosure, the OLED display panel may also be a Passive matrix OLED (PMOLED) display panel. In this case, no thin film transistor is generally disposed in the display area on the first substrate.

In this embodiment, a planarization layer 234 (PLN) is disposed above the first substrate 210. Specifically, in the present embodiment, the planarization layer 234 is disposed on the interlayer insulating layer 233, the data line, the source 244, and the drain 243.

In this embodiment, the auxiliary electrode includes a transfer electrode 221 and a connection electrode. The transfer electrode 221 is used to transmit a voltage signal for transmitting the voltage signal on the transfer electrode 221 to a later-mentioned cathode 246. Specifically, in the present embodiment, the transfer electrode 221 is located between the first substrate 210 and the buffer layer 231. The resistance of the transfer electrode 221 is relatively small, so that the voltage drop caused by the transmission voltage transmitted by the transfer electrode 221 is relatively small, so that the IR drop problem can be improved. In this embodiment, the connection electrode includes a first connection electrode 222 and a second connection electrode 223. The first connection electrode 222 is located between the interlayer insulating layer 223 and the planarization layer 234. That is, the first connection electrode 222 is located on the same metal layer as the data line, the source electrode 244 and the drain electrode 243, wherein the first connection electrode 222 and the transmission electrode 221 are electrically connected by digging holes in the buffer layer 231 and the interlayer insulating layer 233. The second connection electrode 223 is located on the planarization layer 234. The second connection electrode 223 is electrically connected to the first connection electrode 222 by digging holes in the planarization layer 234. In addition, in other embodiments of the present disclosure, the auxiliary electrode may further include only the second connection electrode and the transfer electrode, the transfer electrode is located between the interlayer insulating layer and the planarization layer, the second connection electrode is on the planarization layer, and the second connection electrode is electrically connected to the transfer electrode by digging holes in the planarization layer. In addition, in other embodiments of the present disclosure, the auxiliary electrode may further include only the transfer electrode, and the transfer electrode may be located on the planarization layer. In addition, in other embodiments of the present disclosure, the auxiliary electrode includes a transfer electrode, a first connection electrode and a second connection electrode, the transfer electrode is located on the gate insulating layer. That is, the transfer electrode is located on the same layer as the gate and the scan line, the first connection electrode is located between the interlayer insulating layer and the planarization layer. That is, the first connection electrode is located on the same metal layer as the data line, the source and the drain, and the first connection electrode and the transfer electrode are electrically connected by digging holes in the interlayer insulating layer. The second connection electrode is located on the planarization layer, and the second connection electrode is electrically connected to the first connection electrode by digging holes in the planarization layer. In this embodiment, the auxiliary electrode may be any metal such as Mo, AL, Ti, Cu, or ITO.

In this embodiment, the anode 245 is formed on the planarization layer 234, and the anode 245 and the drain 243 are electrically connected by digging holes in the planarization layer 234. The voltage signal is transmitted to the anode 245 through the conduction or not of the drain electrode 243 of the thin film transistor source 244. In this embodiment, the anode 245 and the second connection electrode 223 are located in the same layer.

In this embodiment, the pixel definition layer 235 is formed on the anode 245, the second connection electrode 223, and the planarization layer 234. The pixel definition layer 235 defines a plurality of pixel regions. Specifically, the pixel definition layer 235 includes a plurality of lateral pixel defining portions extending in the X-axis direction and a plurality of longitudinal pixel defining portions extending in the Y-axis direction. The horizontal definition section and the vertical definition section intersect to form a plurality of pixel regions.

In this embodiment, the number of the cathode isolation columns 250 is plural, the cathode isolation column 250 is disposed adjacent to the pixel definition layer 235, the cathode 246 is formed on the auxiliary electrode, the cathode isolation column 250 has an inverted trapezoid shape.

In this embodiment, the organic light-emitting layer 236 is formed on the pixel region, the pixel defining layer 235, the auxiliary electrode and the cathode isolation column 250 by vapor deposition. The organic light-emitting layer 236 of the pixel region, the adjacent pixel defining layer 235 and the organic light-emitting layer 236 on the auxiliary electrode are integrated into one. Since the height of the cathode isolation column 250 is higher, the organic light-emitting layer 236 in the pixel region is separated from the organic light-emitting layer 236 in the adjacent cathode isolation column 250. In addition, in other embodiments of the present disclosure, the organic light-emitting layer may also be formed by printing.

In this embodiment, the cathode 246 is a transparent metal layer, for example, ITO or the like. The cathode 246 is formed on the organic light-emitting layer 236 by vapor deposition or printing. Here, the anode 245 and the cathode 246 sandwich the organic light-emitting layer 236. In the present embodiment, the cathode 246 includes a light-emitting cathode 246a and an isolation cathode 246b. The light-emitting cathode 246a is located above the pixel region, the pixel defining layer 235, and the organic light-emitting layer 236 of the auxiliary electrode. The isolation cathode 246b is located above the organic light-emitting layer 236 on the cathode isolation column 250. Due to the relative height of the cathode isolation column 250, the light-emitting cathode 246a and the isolation cathode 246b are separated from each other. The cathode 246 is isolated by the cathode isolation column 250, thereby achieving the sole control of the cathode 246 and reducing the problem of IR Drop.

In this embodiment, in order to stably transmit the voltage signal to the cathode 246, an electrode stage 260 is disposed under the cathode isolation column 250, and the number of the electrode stages 260 is equal to the number of the cathode isolation columns 250. In this embodiment, the electrode stage 260 is directly electrically connected to the auxiliary electrode. Specifically, the cathode isolation column 250 is directly connected to the second connection electrode 223 of the auxiliary electrode. The cathode isolation column 250 is formed on the electrode stage 260. The electrode stage 260 is electrically connected to the light-emitting cathode 246a. Specifically, when the light-emitting cathode 246a is formed, it is attached to the sidewall of the electrode stage 260. For example, the side wall of the light-emitting cathode 246a is close to the side wall of the electrode stage 260 or the light-emitting cathode 246a is close to the side wall of the electrode stage 260 and climbs up a distance along the sidewall of the electrode stage 260. Thereby achieving a stable electrical connection between the light-emitting cathode 246a and the electrode stage 260. The light-emitting cathode 246a can be electrically connected to the auxiliary electrode through the electrode stage 260 even though the light-emitting cathode 246a is not directly electrically connected to the second connection electrode 223, so that the voltage signal on the auxiliary electrode is transmitted to the cathode 246. In addition, in other embodiments of the present disclosure, the electrode stage may also be indirectly electrically connected to the auxiliary electrode. In this embodiment, the electrode stage 260 may be any metal such as Mo, AL, Ti, Cu, or ITO.

In the present embodiment, the upper surface of the electrode stage 260 is higher than the upper surface of the edge portion of the light-emitting cathode 246a electrically connected thereto. The electrode stage 260 is not covered by the organic light-emitting layer 236 and does not cause the organic light-emitting layer 236 to block the electrical connection between the subsequent light-emitting cathode 246a and the electrode stage 260. Moreover, the height of the upper surface of the electrode stage 260 is higher, the height of the cathode isolation column 250 above the electrode stage 260 is higher, and the distance between the cathode isolation column 250 and the organic light-emitting layer 236 is greater, so that the light-emitting cathode 246a is not blocked by the inverted trapezoidal cathode isolation column 250 when the light-emitting cathode 246a is formed and the electrical connection between the light-emitting cathode 246a and the electrode stage 260 is not affected because the angle of the cathode isolation column 250 is too small. The edge portions of the light-emitting cathode 246a can be brought into contact with the sidewalls of the electrode stage 260 sufficiently to make electrical connection, thereby preventing the problems of electrical contact between the light-emitting cathode 246a and the electrode stage 260.

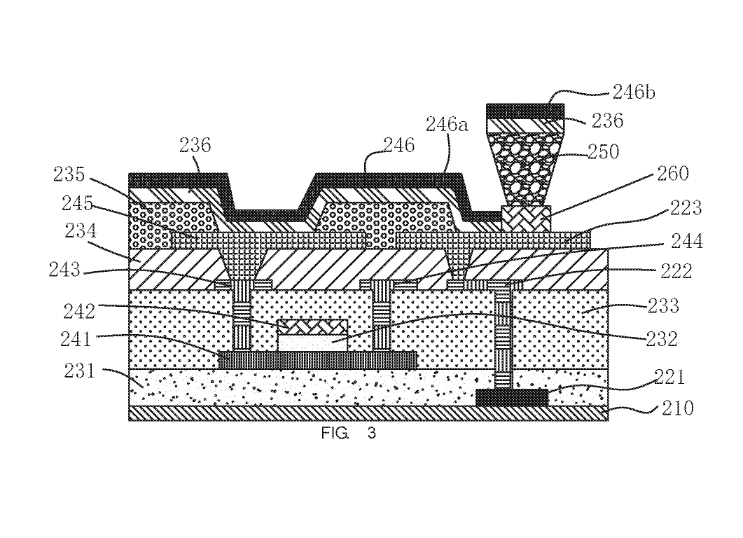

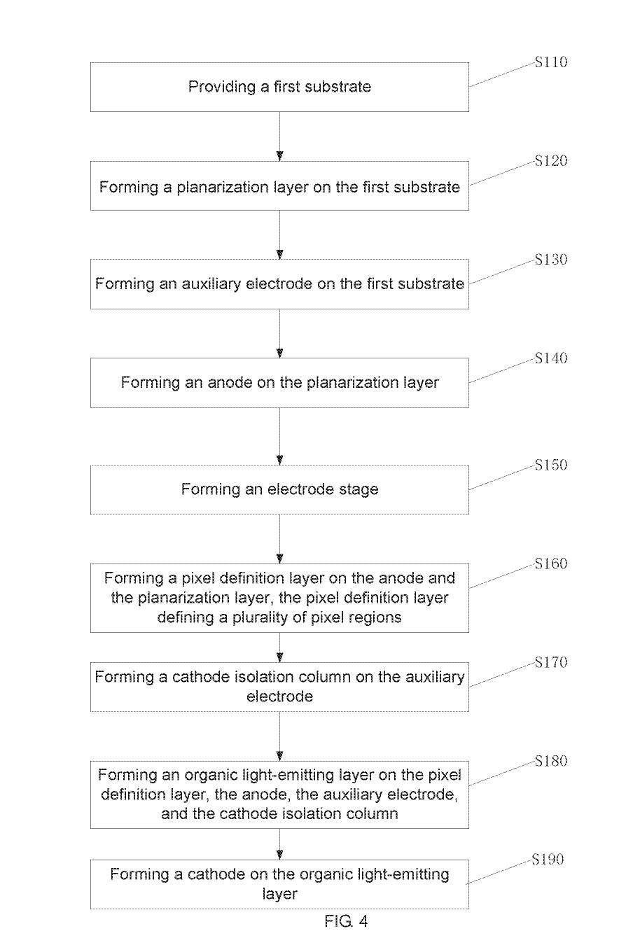

An embodiment of the present disclosure further provides a manufacturing method of an OLED display panel. Referring to FIG. 3 and FIG. 4, the method includes the following steps.

S110. Providing a first substrate 210.

In this embodiment, the first substrate 210 is an array substrate. In this embodiment, the OLED display panel is an Active-matrix organic light-emitting diode (AMOLED) display panel. A thin film transistor is disposed on the first substrate 210. The thin film transistor may be an amorphous silicon thin film transistor or a polycrystalline silicon thin film transistor. In this embodiment, a buffer layer 231 is disposed on the first substrate 210, a semiconductor layer 241 is disposed on the buffer layer 231, the semiconductor layer 241 is an IGZO material. A gate insulating layer 232 is disposed on the semiconductor layer 241. A gate 242 and a scan line is disposed on the gate insulating layer 232. An interlayer insulating layer 233 (ILD) is disposed above the gate 242, the scan line, the semiconductor layer 241 and the buffer layer 231. The interlayer insulating layer 233 is provided with a source 244, a drain 243, a data line. The source 244 is electrically connected to the corresponding data line, and the source 244 and the drain 243 are electrically connected to the two ends of the semiconductor layer 241 through holes.

S120. Forming a planarization layer 234 on the first substrate 210.

S130. Forming an auxiliary electrode on the first substrate 210.

In this embodiment, the auxiliary electrode includes a transfer electrode 221 and a connection electrode. The transfer electrode 221 is located below the planarization layer 234. The connection electrode electrically connects the transfer electrode 221 and the electrode stage 260, respectively. The connection electrode includes a first connection electrode 222 and a second connection electrode 223. The OLED display panel further includes a buffer layer 231, an interlayer insulating layer 233. The buffer layer 231 is located on the first substrate 210, the interlayer insulating layer 233 is located on the buffer layer 231, the planar layer 234 is located on the interlayer insulating layer 233. The transmission electrode 221 is located between the first substrate 210 and the buffer layer 231. The first connection electrode 222 is located on the interlayer insulating layer 233 and electrically connects the first connection electrode 222 with the transmission electrode 221 by digging holes in the interlayer insulating layer 233. The second connection electrode 223 is located on the planarization layer 234 and electrically connects the second connection electrode 223 with the first connection electrode 222 by digging the planarization layer 234.

S140. Forming an anode 245 on the planarization layer 234.

S160. Forming a pixel definition layer 235 on the anode 245 and the planarization layer 234, the pixel definition layer 235 defining a plurality of pixel regions.

S170. Forming a cathode isolation column 250 on the auxiliary electrode.

S180. Forming an organic light-emitting layer 236 on the pixel defining layer 235, the anode 245, the auxiliary electrode, and the cathode isolation column 250.

S190, Forming a cathode 246 on the organic light-emitting layer 236, The cathode 246 includes a light-emitting cathode 246a and an isolation cathode 246b. The light-emitting cathode 246a is disposed on the pixel defining layer 235 and the pixel region. The isolation cathode 246b is disposed on the cathode isolation column 250. The light-emitting cathode 246a and the isolation cathode 246b are isolated from each other by the cathode isolation column 250. The manufacturing method of an OLED display panel further includes the following step.

S150, Forming an electrode stage 260. the electrode stage 260 is electrically connected directly or indirectly to the auxiliary electrode, the cathode isolation column 250 is formed on the electrode stage 260, the electrode stage 260 is electrically connected to the light-emitting cathode 246a for the light-emitting cathode 246a to receive the voltage on the auxiliary electrode.

In this embodiment, the electrode stage 260 is located above the second connection electrode 223. The upper surface of the electrode stage 260 is higher than the upper surface of the edge portion of the light-emitting cathode 246a electrically connected thereto, and the edge portion of the light-emitting cathode 246a is electrically connected to the sidewall of the electrode stage 260.

In this embodiment, one of or both the organic light-emitting layer 236 and the cathode 246 is formed by vapor deposition or printing.

It should be noted that, various embodiments in this specification are described in a progressive manner. Each embodiment focuses on the differences from other embodiments, and the same or similar parts among the embodiments may refer to each other. Since the apparatus embodiment is basically similar to the method embodiments, the description is relatively simple, and for the relevant parts, reference may be made to the part of the method embodiments.

Through the description of the above embodiments, the present disclosure has the following advantages.

Since the OLED display panel includes an electrode stage, the electrode stage is electrically connected with the auxiliary electrode directly or indirectly. The cathode isolation column is formed on the electrode stage and the electrode stage is electrically connected to the light-emitting cathode for the light-emitting cathode to receive a voltage on the auxiliary electrode. Even though the light-emitting cathode is not directly electrically connected to the second connection electrode, the light-emitting cathode can be electrically connected to the auxiliary electrode through the electrode stage, so that the voltage signal on the auxiliary electrode is stably transmitted to the cathode.

The above disclosure is only the preferred embodiments of the present disclosure, and certainly can not be used to limit the scope of the present disclosure. Therefore, equivalent changes made according to the claims of the present disclosure are still within the scope of the present disclosure.

1. An OLED display panel, comprising:
a first substrate;
a planarization layer formed on the first substrate;
an auxiliary electrode formed on the first substrate;
an anode formed on the planarization layer;
a pixel definition layer formed on the anode and the planarization layer, the pixel definition layer defining a plurality of pixel regions;
a cathode isolation column formed on the auxiliary electrode;
an organic light-emitting layer formed on the pixel definition layer, the anode, the auxiliary electrode, and the cathode isolation column;
a cathode formed on the organic light-emitting layer, the cathode comprising a light-emitting cathode and an isolation cathode, the light-emitting cathode being disposed on the pixel definition layer and the pixel region, the isolation cathode being disposed on the cathode isolation column, the light-emitting cathode and the isolation cathode are isolated from each other by the cathode isolation column; and
an electrode stage electrically connected to the auxiliary electrode,
wherein the cathode isolation column is formed on the electrode stage electrically connected to the light-emitting cathode for the light-emitting cathode to receive a voltage on the auxiliary electrode.

2. The OLED display panel according to claim 1, wherein an upper surface of the electrode stage is higher than an upper surface of an edge portion of the light-emitting cathode electrically connected thereto, and the edge portion of the light-emitting cathode is electrically connected to a sidewall of the electrode stage.

3. The OLED display panel according to claim 1, wherein the auxiliary electrode comprises a transfer electrode and a connection electrode, the transfer electrode is located below the planarization layer, and the connection electrode electrically connects the transfer electrode and the electrode stage respectively.

4. The OLED display panel according to claim 3, wherein the connection electrode comprises a first connection electrode and a second connection electrode, the OLED display panel further comprises a buffer layer and an interlayer insulating layer, the buffer layer is located on the first substrate, the interlayer insulating layer is located on the buffer layer, the planarization layer is located on the interlayer insulating layer, wherein the transfer electrode is located between the first substrate and the buffer layer, the first connection electrode is located on the interlayer insulating layer and electrically connected to the transfer electrode by a dug hole on the interlayer insulating layer, the second connection electrode is located on the planarization layer and electrically connected to the first connection electrode by a dug hole on the planarization layer, the electrode stage is located above the second connection electrode.

5. The OLED display panel according to claim 1, wherein one of or both the organic light-emitting layer and the cathode is formed by vapor deposition or printing.

6. A manufacturing method of an OLED display panel, comprising:
providing a first substrate;
forming a planarization layer on the first substrate;
forming an auxiliary electrode on the first substrate;
forming an anode on the planarization layer;
forming a pixel definition layer on the anode and the planarization layer, the pixel definition layer defining a plurality of pixel regions;
forming a cathode isolation column on the auxiliary electrode;
forming an organic light-emitting layer on the pixel definition layer, the anode, the auxiliary electrode, and the cathode isolation column;
forming a cathode on the organic light-emitting layer, the cathode comprising a light-emitting cathode and an isolation cathode, the light-emitting cathode being disposed on the pixel definition layer and the pixel region, the isolation cathode being disposed on the cathode isolation column, the light-emitting cathode and the isolation cathode being isolated from each other by the cathode isolation column; wherein the manufacturing method of an OLED display panel further comprises:
forming an electrode stage electrically connected to the auxiliary electrode,
wherein the cathode isolation column is formed on the electrode stage electrically connected to the light-emitting cathode for the light-emitting cathode to receive a voltage on the auxiliary electrode.

7. The manufacturing method of an OLED display panel according to claim 6, wherein an upper surface of the electrode stage is higher than an upper surface of an edge portion of the light-emitting cathode electrically connected thereto, and the edge portion of the light-emitting cathode is electrically connected to a sidewall of the electrode stage.

8. The manufacturing method of an OLED display panel according to claim 6, wherein the auxiliary electrode comprises a transfer electrode and a connection electrode, the transfer electrode is located below the planarization layer, and the connection electrode electrically connects the transfer electrode and the electrode stage respectively.

9. The manufacturing method of an OLED display panel according to claim 8, wherein the connection electrode comprises a first connection electrode and a second connection electrode, the OLED display panel further comprises a buffer layer and an interlayer insulating layer, the buffer layer is located on the first substrate, the interlayer insulating layer is located on the buffer layer, the planarization layer is located on the interlayer insulating layer, wherein the transfer electrode is located between the first substrate and the buffer layer, the first connection electrode is located on the interlayer insulating layer, and electrically connected to the transfer electrode by a dug hole on the interlayer insulating layer, the second connection electrode is located on the planarization layer and electrically connected to the first connection electrode by a dug hole on the planarization layer, the electrode stage is located above the second connection electrode.

10. The manufacturing method of an OLED display panel according to claim 6, wherein one of or both the organic light-emitting layer and the cathode is formed by vapor deposition or printing.
